(19) United States
(12) Patent Application Publication
(10) Pub. No.: US 2025/0107378 A1
(43) Pub. Date: Mar. 27, 2025

(54) DISPLAY DEVICE AND METHOD OF MANUFACTURING THE SAME

(71) Applicant: Samsung Display Co., LTD., Yongin-si (KR)

(72) Inventors: NAHYEON CHA, Yongin-si (KR); SUNKWUN SON, Yongin-si (KR); DONG HEE SHIN, Yongin-si (KR)

(21) Appl. No.: 18/769,173

(22) Filed: Jul. 10, 2024

(30) Foreign Application Priority Data
Sep. 22, 2023 (KR) 10-2023-0127379

(51) Int. Cl. H10K 59/131; H10K 59/12; H10K 59/122; H10K 71/60

(52) U.S. Cl. CPC H10K 59/1315; H10K 59/1201; H10K 59/122; H10K 71/60

(57) ABSTRACT

A display device includes: a first auxiliary insulating layer through which an opening is defined; a second auxiliary insulating layer on the first auxiliary insulating layer; a pixel definition layer on the second auxiliary insulating layer and having a pixel opening defined therethrough; a first auxiliary electrode having at least a portion in the opening; a second auxiliary electrode having at least a portion in the opening, the second auxiliary electrode comprising a second-first portion on the first auxiliary electrode and a second-second portion comprising a first surface that forms a first angle with an upper surface of the first auxiliary electrode and is spaced apart from the upper surface of the first auxiliary electrode; a first electrode having a portion in the pixel opening; and a second electrode on the first electrode and electrically connected to the first auxiliary electrode.

The present application claims priority to and the benefit of Korean Patent Application No. 10-2023-0127379, filed on Sep. 22, 2023, in the Korean Intellectual Property Office, the entire disclosure of which is incorporated herein by reference.

### BACKGROUND

### 1. Field

Aspects of some embodiments of the present disclosure relate to a display device and a method of manufacturing the same.

### 2. Description of the Related Art

Various display devices applied to multimedia devices, such as televisions, mobile phones, tablet computers, computers, and game devices, are being developed. Research is being conducted on reducing the size of pixels and increasing integration of the pixels to relatively improve a resolution of display devices. Display devices employing a large-sized display panel may have a large area, and thus a resistance of electrodes may be relatively large compared with small and medium-sized display panels. In a case where a surface area of an opening formed to reduce the resistance of the electrodes increases, a degree of integration may decrease.

The above information disclosed in this Background section is only for enhancement of understanding of the background and therefore the information discussed in this Background section does not necessarily constitute prior art.

### SUMMARY

Aspects of some embodiments of the present disclosure relate to a display device and a method of manufacturing the same. For example, aspects of some embodiments of the present disclosure relate to a display device capable of relatively reducing a resistance of electrodes thereof to relatively improve an efficiency thereof and a method of manufacturing the display device.

Aspects of some embodiments of the present disclosure include a display device capable of relatively reducing a resistance of electrodes.

Aspects of some embodiments of the present disclosure include a method of manufacturing the display device.

Aspects of some embodiments may identify an optimal point between improving of the resistance of the electrodes and decreasing of integration.

According to some embodiments of the present disclosure, a display device includes: a first auxiliary insulating layer through which an opening is defined, a second auxiliary insulating layer on the first auxiliary insulating layer, a pixel definition layer on the second auxiliary insulating layer and provided with a pixel opening defined therethrough, a first auxiliary electrode whose at least a portion is in the opening, a second auxiliary electrode whose at least a portion is in the opening, a first electrode whose at least a portion is in the pixel opening, and a second electrode on the first electrode and electrically connected to the first auxiliary electrode. According to some embodiments, the second auxiliary electrode includes a second-first portion on the first auxiliary electrode and a second-second portion including a first surface that forms a first angle with an upper surface of the first auxiliary electrode and spaced apart from the upper surface of the first auxiliary electrode.

According to some embodiments, the second-second portion is in the opening.

According to some embodiments, a portion of the second auxiliary insulating layer is on the second auxiliary electrode.

According to some embodiments, the first angle is an acute angle.

According to some embodiments, the second-first portion is directly on the first auxiliary electrode.

According to some embodiments, the second auxiliary electrode includes a second surface forming a second angle with the upper surface of the first auxiliary electrode and further includes a second-third portion spaced apart from the upper surface of the first auxiliary electrode.

According to some embodiments, the second angle is an acute angle.

According to some embodiments, the pixel opening does not overlap the opening when viewed in a plane (or in a plan view).

According to some embodiments, the second auxiliary electrode has an area smaller than an area of the first auxiliary electrode when viewed in the plane (or in a plan view)).

According to some embodiments, the opening has a diameter equal to or greater than about 10 micrometers and equal to or smaller than about 15 micrometers when viewed in the plane (or in a plan view).

According to some embodiments, the display device further includes an intermediate layer between the first electrode and the second electrode, and a portion of the intermediate layer overlaps the pixel opening when viewed in the plane (or in a plan view).

According to some embodiments, the intermediate layer includes a first contact portion directly on the first auxiliary electrode, the second electrode includes a second contact portion electrically connected to the first auxiliary electrode, and the second contact portion is between the first contact portion and the first surface and overlaps the second-second portion when viewed in the plane (or in a plan view).

According to some embodiments of the present disclosure, a display device includes: a base layer, a circuit element layer on the base layer, and a display element layer on the circuit element layer and including a pixel definition layer and a light emitting element. According to some embodiments, the circuit element layer includes a first auxiliary insulating layer through which an opening is defined, a second auxiliary insulating layer on the first auxiliary insulating layer, a first auxiliary electrode whose at least a portion is in the opening, and a second auxiliary electrode whose at least a portion is in the opening. According to some embodiments, the second auxiliary electrode includes a second-first portion on the first auxiliary electrode and a second-second portion including a first surface that forms a first angle with an upper surface of the first auxiliary electrode and spaced apart from the upper surface of the first auxiliary electrode. According to some embodiments, the pixel definition layer is on the second auxiliary insulating layer and provided with a pixel opening defined therethrough. According to some embodiments, the light emitting element includes a first electrode whose at least a portion is in the pixel opening, a second electrode on the first electrode and electrically connected to the first auxiliary electrode, and an intermediate layer between the first electrode and the second electrode, and at least a portion of the intermediate layer is in the pixel opening.

According to some embodiments, the opening does not overlap the pixel opening when viewed in a plane (or in a plan view).

According to some embodiments, the display device further includes an encapsulation layer on the display element layer.

According to some embodiments of the present disclosure, in a method of manufacturing a display device, the method includes: forming a first auxiliary insulating layer on a first auxiliary electrode, forming a preliminary opening through the first auxiliary insulating layer to overlap the first auxiliary electrode when viewed in a plane (or in a plan view), forming a second auxiliary electrode in the preliminary opening and including a second-first portion on the first auxiliary electrode and a second-second portion including a first surface that forms a first angle with an upper surface of the first auxiliary electrode and spaced apart from the upper surface of the first auxiliary electrode, forming a second auxiliary insulating layer on the first auxiliary insulating layer and the second auxiliary electrode, placing a mask provided with a first hole defined therethrough and overlapping the preliminary opening above the second auxiliary insulating layer, etching a portion of the first auxiliary insulating layer, which overlaps the first hole when viewed in the plane (or in a plan view), and a portion of the second auxiliary insulating layer, which overlaps the first hole when viewed in the plane (or in a plan view), to form an opening through which the second-second portion and the portion of the first auxiliary electrode are exposed, forming a first electrode that does not overlap the opening and an intermediate layer on the first electrode, and forming a second electrode on the intermediate layer and electrically connected to the first auxiliary electrode.

According to some embodiments, the etching to form the opening is performed by a dry etching process.

According to some embodiments, the second auxiliary electrode further includes a second-third portion including a second surface that forms a second angle with the upper surface of the first auxiliary electrode, and the first hole overlaps the second-second portion, at least a portion of the first auxiliary insulating layer, and the second-third portion when viewed in the plane (or in a plan view).

According to some embodiments, the first hole does not overlap the second-first portion when viewed in the plane (or in a plan view).

According to some embodiments, the method further includes etching a portion of the first auxiliary insulating layer which overlap the first auxiliary electrode when viewed in the plane (or in a plan view) and do not overlap the second auxiliary electrode when viewed in the plane (or in a plan view), and a portion of the second auxiliary insulating layer to form a sub-opening before the forming of the opening, and a depth of the opening is greater than a depth of the sub-opening.

According to some embodiments of the present disclosure, the second electrode included in the display device is electrically connected to the first auxiliary electrode that is exposed through the opening. Thus, a resistance of the electrode may be relatively reduced to relatively improve an efficiency of the display device, and the size of the opening may be small enough not to allow a degree of pixel integration to significantly decrease.

According to some embodiments, the opening may be relatively easily formed by the etching process using the mask including the hole defined therethrough, and a difficulty in the process of manufacturing the display device may be relatively reduced.

### BRIEF DESCRIPTION OF THE DRAWINGS

The above and other characteristics of some embodiments of the present disclosure will become more readily apparent by reference to the following detailed description when considered in conjunction with the accompanying drawings wherein:

FIG. 1 is a perspective view of a display device according to some embodiments of the present disclosure;

FIG. 2 is an exploded perspective view of a display device according to some embodiments of the present disclosure;

FIG. 3 is a cross-sectional view of a display device according to some

embodiments of the present disclosure;

FIG. 4 is a plan view of a display panel according to some embodiments of the present disclosure;

FIG. 5 is an enlarged plan view of an active area of a display panel according to some embodiments of the present disclosure;

FIG. 6 is a cross-sectional view of a display device taken along a line I-I′ of FIG. 5 according to some embodiments of the present disclosure;

FIGS. 7 and 8 are cross-sectional views of display devices taken along a line II-II′ of FIG. 5 according to some embodiments of the present disclosure;

FIG. 9 is a flowchart of a method of manufacturing a display device according to some embodiments of the present disclosure;

FIG. 10 is a cross-sectional view of a process of the manufacturing method of the display device according to some embodiments of the present disclosure;

FIG. 11 is a cross-sectional view of a process of the manufacturing method of the display device according to some embodiments of the present disclosure;

FIG. 12 is a cross-sectional view of a process of the manufacturing method of the display device according to some embodiments of the present disclosure;

FIG. 13 is a cross-sectional view of a process of the manufacturing method of the display device according to some embodiments of the present disclosure;

FIG. 14 is a cross-sectional view of a process of the manufacturing method of the display device according to some embodiments of the present disclosure;

FIG. 15 is a cross-sectional view of a process of the manufacturing method of the display device according to some embodiments of the present disclosure;

FIG. 16 is a cross-sectional view of a process of the manufacturing method of the display device according to some embodiments of the present disclosure;

FIG. 17 is a cross-sectional view of a process of the manufacturing method of the display device according to some embodiments of the present disclosure;

FIG. 18 is a cross-sectional view of a process of the manufacturing method of the display device according to some embodiments of the present disclosure; and

FIG. 19 is a cross-sectional view of a process of the manufacturing method of the display device according to some embodiments of the present disclosure.

### DETAILED DESCRIPTION

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Meanwhile, in the present disclosure, when an element is referred to as being “directly connected” to another element, there are no intervening elements present between a layer, film region, or substrate and another layer, film, region, or substrate. For example, the term “directly connected” may mean that two layers or two members are arranged without employing additional adhesive therebetween.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, aspects of some embodiments of the present disclosure will be described in more detail with reference to accompanying drawings.

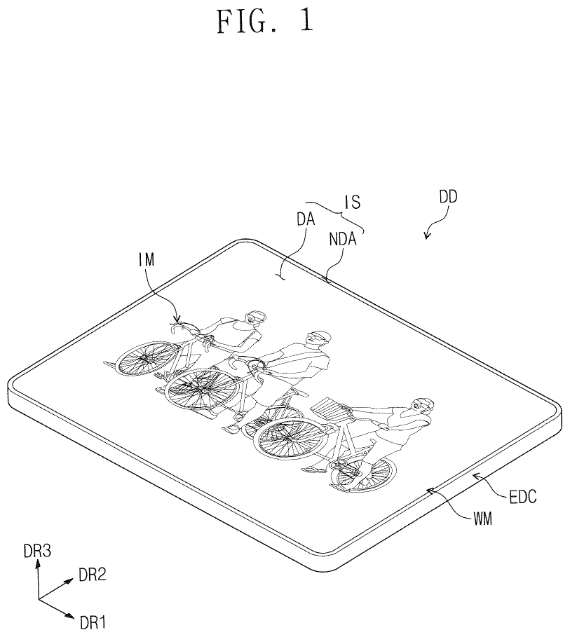

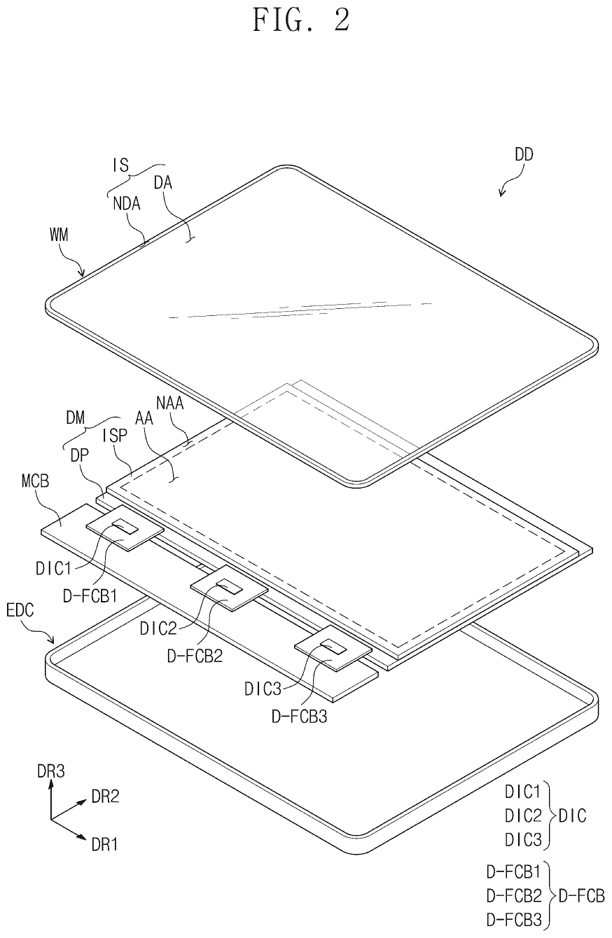

FIG. 1 is a perspective view of a display device DD according to some embodiments of the present disclosure. FIG. 2 is an exploded perspective view of the display device DD according to some embodiments of the present disclosure.

Referring to FIGS. 1 and 2, the display device DD may be a device activated in response to electrical signals. The display device DD may be applied to a large-sized display device, such as a television set or a monitor. However, these are merely examples, and the display device DD may be applied to other electronic devices without departing from the spirit and scope of embodiments according to the present disclosure. The display device DD may have a rectangular shape defined by long sides extending in a first direction DR1 and short sides extending in a second direction DR2 intersecting the first direction DR1. However, the shape of the display device DD should not be limited to the rectangular shape, and the display device DD may have a variety of shapes (e.g., a circular, elliptical, polygonal, irregular shape, and the like). The display device DD may display an image IM toward a third direction DR3 through a display surface IS that is substantially parallel to each of the first direction DR1 and the second direction DR2. The display surface IS through which the image IM is displayed may correspond to a front surface of the display device DD.

In the present embodiments, front (or upper) and rear (or lower) surfaces of each member may be defined with respect to the direction in which the image IM is displayed. The front and rear surfaces may be opposite to each other in the third direction DR3, and a normal line direction of each of the front and rear surfaces may be substantially parallel to the third direction DR3.

A separation distance in the third direction DR3 between the front surface and the rear surface may correspond to a thickness in the third direction DR3 of the display device DD. Meanwhile, directions indicated by the first, second, and third directions DR1, DR2, and DR3 may be relative to each other and may be changed to other directions.

The display device DD may sense an external input applied thereto from the outside. The external input may include inputs of various forms provided from the outside of the display device DD. The display device DD may sense an external input generated by a user and applied thereto. The external input by the user may include one of various forms of external inputs, such as a portion of the user's body (e.g., a user's finger), light, heat, gaze, or pressure, or a combination thereof. In addition, the display device DD may sense the external input applied to a side surface or a rear surface thereof by the user according to a structure thereof. However, embodiments according to the present disclosure are not limited thereto or thereby. According to some embodiments, the external input may include inputs generated by an input device, e.g., a stylus pen, an active pen, a touch pen, an electronic pen, an e-pen, or the like.

The display surface IS of the display device DD may include a display area DA and a non-display area NDA. The display area DA may be an area in which the image IM is displayed. The user may view the image IM in the display area DA. According to some embodiments, the display area DA may have a quadrangular shape with rounded vertices, however, this is merely an example. The display area DA may have a variety of shapes and should not be particularly limited.

The non-display area NDA may be defined adjacent to (e.g., in a periphery or outside a footprint of) the display area DA. The non-display area NDA may have a color (e.g., a set or predetermined color). The non-display area NDA may surround the display area DA. Accordingly, the display area DA may have a shape substantially defined by the non-display area NDA, however, this is merely an example. According to some embodiments, the non-display area NDA may be located adjacent to only one side of the display area DA or may be omitted. The display device DD may include various embodiments and should not be particularly limited.

Referring to FIG. 2, the display device DD may include a display module DM and a window WM located on the display module DM. The display module DM may include a display panel DP and an input sensing layer ISP.

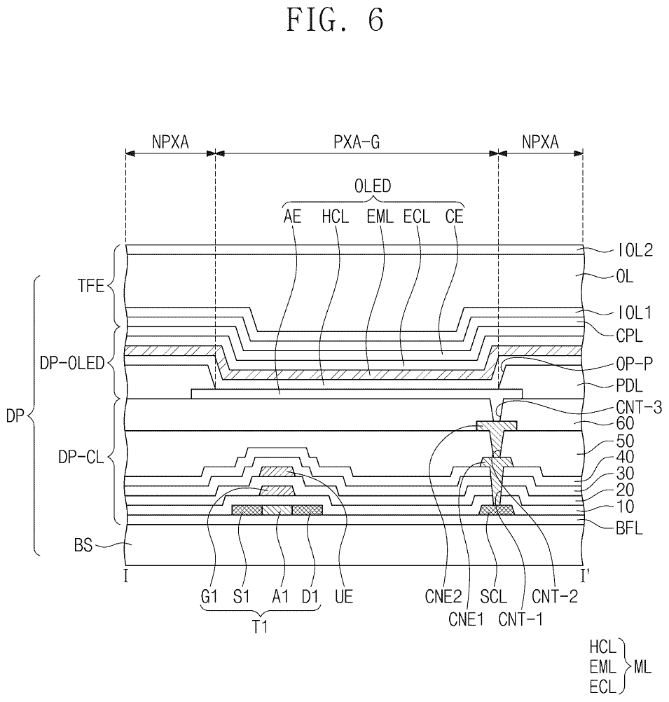

According to some embodiments, the display panel DP may be a light-emitting type of display panel. As an example, the display panel DP may be an organic light emitting display panel. A light emitting layer EML (refer to FIG. 6) of the organic light emitting display panel may include an organic light emitting material.

The display panel DP may output the image IM, and the output image IM may be displayed through the display surface IS.

The input sensing layer ISP may be located on the display panel DP and may sense the external input. The input sensing layer ISP may be located directly on the display panel DP. According to some embodiments, the input sensing layer ISP may be formed on the display panel DP through successive processes. That is, when the input sensing layer ISP is located directly on the display panel DP, an inner adhesive film may not be located between the input sensing layer ISP and the display panel DP. However, the inner adhesive film may be located between the input sensing layer ISP and the display panel DP. In this case, the input sensing layer ISP may not be manufactured through the successive processes with the display panel DP, and the input sensing layer ISP may be fixed to an upper surface of the display panel DP by the inner adhesive film after being manufactured through a separate process.

The window WM may include a transparent material through which the image IM transmits. For example, the window WM may include glass, sapphire, or plastic. The window WM is shown as a single layer, however, it should not be limited thereto or thereby. The window WM may include a plurality of layers.

Meanwhile, according to some embodiments, the non-display area NDA of the display device DD may be obtained by printing a material having the color (e.g., the set or predetermined color) on an area of the window WM. As an example, the window WM may include a light blocking pattern to define the non-display area NDA.

The light blocking pattern may be a colored organic layer and may be formed by a coating method.

The window WM may be coupled to the display module DM by an adhesive film. As an example, the adhesive film may include an optically clear adhesive film (OCA). However, the adhesive film should not be limited thereto or thereby, and the adhesive film may include any suitable adhesive material. For example, the adhesive film may include an optically clear resin (OCR) or a pressure sensitive adhesive film (PSA).

An anti-reflective layer may be further located between the window WM and the display module DM. The anti-reflective layer may reduce a reflectance with respect to an external light incident thereto from the above of the window WM. The anti-reflective layer according to some embodiments of the present disclosure may include a retarder and a polarizer. The retarder may be a film type or liquid crystal coating type and may include a \/2 retarder and/or a N/4 retarder. The polarizer may be a film type or liquid crystal coating type. The film type polarizer and retarder may include a stretching type synthetic resin film, and the liquid crystal coating type polarizer and retarder may include liquid crystals aligned in an alignment (e.g., a set or predetermined alignment). The retarder and the polarizer may be implemented as one polarizing film.

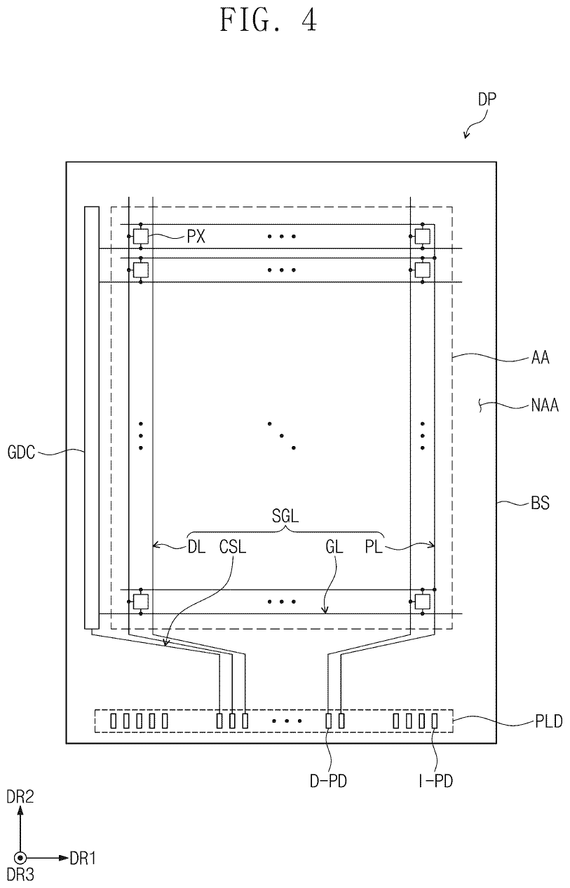

As an example, the anti-reflective layer may include color filters. An arrangement of the color filters may be determined by taking into account colors of lights generated by pixels PX (refer to FIG. 4) included in the display panel DP. In this case, the anti-reflective layer may further include a light blocking pattern located between the color filters.

The display module DM may display the image IM (refer to FIG. 1) in response to electrical signals and may transmit/receive information on the external input. The display module DM may include an active area AA and a peripheral area NAA, which are defined therein. The active area AA may be defined as an area through which the image IM (refer to FIG. 1) provided from the display panel DP exits, i.e., an area through which the image IM (refer to FIG. 1) is displayed. In addition, the active area AA may be defined as an area where the input sensing layer ISP senses the external input applied thereto from the outside. According to some embodiments, the active area AA of the display module DM may correspond to or overlap at least a portion of the display area DA.

The peripheral area NAA may be defined adjacent to the active area AA. The peripheral area NAA may be an area where the image IM is not displayed. For instance, the peripheral area NAA may surround the active area AA. However, this is merely an example, and the peripheral area NAA may be defined in various shapes and should not be particularly limited. According to some embodiments, the peripheral area NAA of the display module DM may correspond to or overlap at least a portion of the non-display area NDA.

The display module DM may further include a main circuit board MCB, flexible circuit films D-FCB, and driving chips DIC. The main circuit board MCB may be connected to the flexible circuit films D-FCB and may be electrically connected to the display panel DP. The flexible circuit films D-FCB may be connected to the display panel DP to electrically connect the display panel DP to the main circuit board MCB. The main circuit board MCB may include a plurality of driving elements. The driving elements may include a circuit unit to drive the display panel DP. The driving chips DIC may be mounted on the flexible circuit films D-FCB.

As an example, the flexible circuit films D-FCB may include a first flexible circuit film D-FCB1, a second flexible circuit film D-FCB2, and a third flexible circuit film D-FCB3. As an example, the driving chips DIC may include a first driving chip DIC1, a second driving chip DIC2, and a third driving chip DIC3. The first, second, and third flexible circuit films D-FCB1, D-FCB2, and D-FCB3 may be arranged spaced apart from each other in the first direction DR1 and may be connected to the display panel DP, and thus, the display panel DP may be electrically connected to the main circuit board MCB. The first driving chip DIC1 may be mounted on the first flexible circuit film D-FCB1, and the second driving chip DIC2 may be mounted on the second flexible circuit film D-FCB2. The third driving chip DIC3 may be mounted on the third flexible circuit film D-FCB3. However, embodiments according to the present disclosure are not limited thereto or thereby. As an example, the display panel DP may be electrically connected to the main circuit board MCB via one flexible circuit film, and only one driving chip may be mounted on the one flexible circuit film. In addition, the display panel DP may be electrically connected to the main circuit board MCB via four or more flexible circuit films, and the driving chips may be respectively mounted on the flexible circuit films.

FIG. 2 shows a structure in which the first, second, and third driving chips DIC1, DIC2, and DIC3 are respectively mounted on the first, second, and third flexible circuit films D-FCB1, D-FCB2, and D-FCB3, however, the present disclosure should not be limited thereto or thereby. As an example, the first, second, and third driving chips DIC1, DIC2, and DIC3 may be directly mounted on the display panel DP. In this case, portions of the display panel DP on which the first, second, and third driving chips DIC1, DIC2, and DIC3 are mounted may be bent and may be located on a rear surface of the display module DM. Alternatively, the first, second, and third driving chips DIC1, DIC2, and DIC3 may be directly mounted on the main circuit board MCB.

The input sensing layer ISP may be electrically connected to the main circuit board MCB via the flexible circuit films D-FCB, however, embodiments according to the present disclosure are not limited thereto or thereby. That is, the display module DM may further include a separate flexible circuit film to electrically connect the input sensing layer ISP to the main circuit board MCB.

The display device DD may further include an external case EDC accommodating the display module DM. The external case EDC may be coupled with the window WM to define an exterior of the display device DD. The external case EDC may absorb impacts applied thereto from the outside and may prevent foreign substances/moisture from entering the display module DM to protect components accommodated in the external case EDC. Meanwhile, as an example, the external case EDC may be obtained by assembling a plurality of accommodating members.

The display device DD may further include an electronic module including various functional modules to operate the display module DM, a power supply module, e.g., a battery, supplying a power source required for an overall operation of the display device DD, and a bracket coupled with the display module DM and/or the external case EDC to divide an inner space of the display device DD.

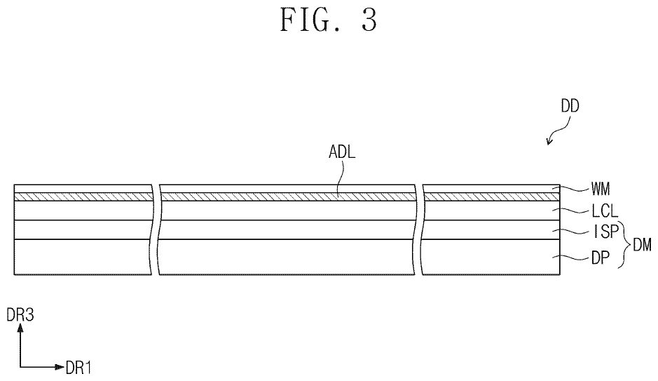

FIG. 3 is a cross-sectional view of the display device DD according to some embodiments of the present disclosure. In FIG. 3, the display device DD is simply shown to illustrate a stacking relationship of functional panels and/or functional units constituting the display device DD.

The display device DD may include the display module DM, a light control layer LCL, and the window WM. The display module DM may include the display panel DP and the input sensing layer ISP. According to some embodiments, the input sensing layer ISP may be omitted.

The display panel DP may generate images. The display panel DP may include the pixels PX (refer to FIG. 4). The display panel DP may be a light emitting type display panel including a light emitting element as its display element, however, the present disclosure should not be limited thereto or thereby. For instance, the display panel DP may be an organic light emitting display panel. A light emitting layer of the organic light emitting display panel may include an organic light emitting material. Hereinafter, the organic light emitting display panel will be described as the display panel DP, but embodiments according to the present disclosure are not limited thereto.

The input sensing layer ISP may be located on the display panel DP. The input sensing layer ISP may obtain coordinate information on the external input, e.g., a touch event. The input sensing layer ISP may sense the external input by a capacitive method.

The light control layer LCL may be located on the input sensing layer ISP. The light control layer LCL may control a path of a light generated by the display panel DP. In addition, the light control layer LCL may reduce a reflectance with respect to a natural light (or a sunlight) incident thereto from above the window WM.

The window WM may be located on the light control layer LCL. The window WM may be coupled with the light control layer LCL by a window adhesive layer ADL. The window adhesive layer ADL may be a pressure sensitive adhesive (PSA) film or an optically clear adhesive (OCA).

FIG. 4 is a plan view of the display panel DP according to some embodiments of the present disclosure.

Referring to FIG. 4, the display panel DP may include a base layer BS including an active area AA and a peripheral area NAA. The display panel DP may include the pixels PX arranged in the active area AA and signal lines SGL electrically connected to the pixels PX. The display panel DP may include a driving circuit GDC and a pad part PLD, which are arranged in the peripheral area NAA.

The pixels PX may be arranged in the first direction DR1 and the second direction DR2. The pixels PX may include a plurality of pixel rows extending in the first direction DR1 and arranged in the second direction DR2 and a plurality of pixel columns extending in the second direction DR2 and arranged in the first direction DR1.

The signal lines SGL may include gate lines GL, data lines DL, a power line PL, and a control signal line CSL. Each of the gate lines GL may be connected to a corresponding pixel among the pixels PX, and each of the data lines DL may be connected to a corresponding pixel among the pixels PX. The power line PL may be electrically connected to the pixels PX. The control signal line CSL may be connected to the driving circuit GDC and may provide control signals to the driving circuit GDC.

The driving circuit GDC may include a gate driving circuit. The gate driving circuit may generate a plurality of gate signals and may sequentially output the gate signals to the gate lines GL. The gate driving circuit may further output other control signals to a driving circuit of the pixel.

The pad part PLD may include pixel pads D-PD and input pads I-PD.

The pixel pads D-PD may be pads to connect the flexible circuit films D-FCB (refer to FIG. 2) to the display panel DP. Each of the pixel pads D-PD may be connected to a corresponding signal line among the signal lines SGL. The pixel pads D-PD may be connected to corresponding pixels among the pixels PX via the signal lines SGL. In addition, one pixel pad among the pixel pads D-PD may be connected to the driving circuit GDC.

The input pads I-PD may be pads to electrically connect the flexible circuit films D-FCB (refer to FIG. 2) to the input sensing layer ISP (refer to FIG. 3). FIG. 4 shows the structure in which the input pads I-PD are located in the display panel DP, however, the present disclosure should not be limited thereto or thereby. According to some embodiments, the input pads I-PD may be located in the input sensing layer ISP (refer to FIG. 3) and may be connected to a separate circuit board different from a circuit board to which the pixel pads D-PD are connected.

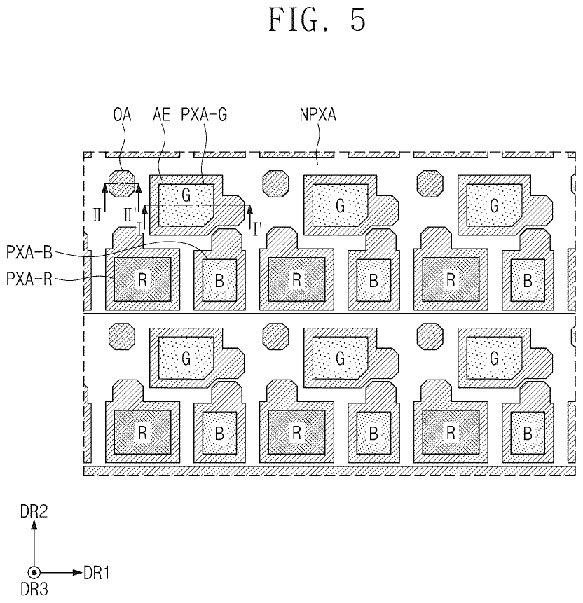

FIG. 5 is an enlarged plan view of the active area of the display panel according to some embodiments of the present disclosure. FIG. 5 shows an arrangement relationship between an opening area OA, a first pixel area PXA-B, a second pixel area PXA-R, and a third pixel area PXA-G when viewed in a direction facing the front surface of the display device DD.

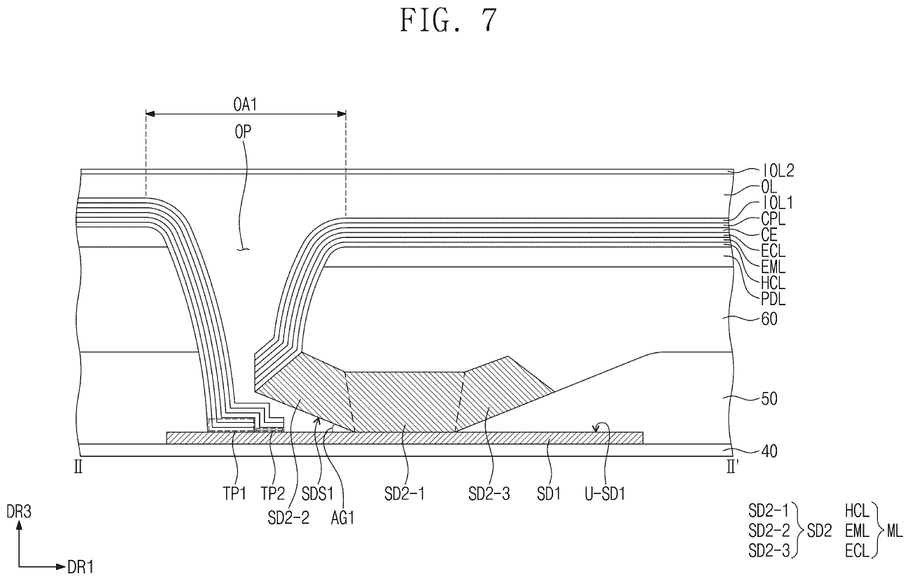

Referring to FIG. 5, the opening area OA may be provided in plural and may not overlap the first, second, and third pixel areas PXA-B, PXA-R, and PXA-G when viewed in the plane (or in a plan view, or when viewed from the third direction DR3). Each of the first pixel area PXA-B, the second pixel area PXA-R, and the third pixel area PXA-G may be provided in plural. The opening areas OA may be alternately arranged with the third pixel areas PXA-G in the first direction DR1 when viewed in the plane (or in a plan view, or when viewed from the third direction DR3). The opening areas OA may be alternately arranged with the second pixel areas PXA-R in the second direction DR2 when viewed in the plane (or in a plan view, or when viewed from the third direction DR3). This arrangement described above is merely an example, and according to some embodiments, each of the opening areas OA may be located between the first pixel area PXA-B and the second pixel area PXA-R in the first direction DR1. The opening areas OA may include a first opening area OA1 (refer to FIG. 7) and a second opening area OA2 (refer to FIG. 8), which have different sizes from each other, and the size of the first opening area OA1 (refer to FIG. 7) may be smaller than the size of the second opening area OA2 (refer to FIG. 8) when viewed in the plane (or in a plan view, or when viewed from the third direction DR3). As the size of the opening area OA decreases, the pixel areas PXA-B, PXA-R, and PXA-G may be arranged to be closer to each other, and thus, a degree of integration of the display panel DP may be improved.

The first and second pixel areas PXA-B and PXA-R may be alternately arranged with each other in the first direction DR1 when viewed in the plane (or in a plan view, or when viewed from the third direction DR3). The third pixel areas PXA-G may be arranged in a different pixel row from the first and second pixel areas PXA-B and PXA-R, and the third pixel areas PXA-G may be arranged in the same pixel row along the first direction DR1. The first and second pixel areas PXA-B and PXA-R may be alternately arranged with each other in the first direction DR1. The arrangement of the first, second, and third pixel areas PXA-B, PXA-R, and PXA-G should not be limited thereto or thereby.

A non-light-emitting area NPXA may not overlap the opening area OA and the first, second, and third pixel areas PXA-B, PXA-R, and PXA-G when viewed in the plane (or in a plan view, or when viewed from the third direction DR3). In FIG. 5, a remaining area except the opening area OA and the first, second, and third pixel areas PXA-B, PXA-R, and PXA-G may be the non-light-emitting area NPXA. The opening area OA and the first, second, and third pixel areas PXA-B, PXA-R, and PXA-G may be surrounded by the non-light-emitting area NPXA when viewed in the plane (or in a plan view, or when viewed from the third direction DR3).

A first electrode AE may overlap the opening area OA and the first, second, and third pixel areas PXA-B, PXA-R, and PXA-G when viewed in the plane (or in a plan view, or when viewed from the third direction DR3). A portion of the first electrode AE may overlap the non-light-emitting area NPXA when viewed in the plane (or in a plan view, or when viewed from the third direction DR3).

FIG. 6 is a cross-sectional view of the display device taken along a line I-I′ of FIG. 5 according to some embodiments of the present disclosure. The line I-I′ of FIG. 5 is shown to cross the third pixel area PXA-G, and descriptions of the third pixel area PXA-G may be applied to the first and second pixel areas PXA-B and PXA-R. Hereinafter, components of the display panel DP will be described.

Referring to FIG. 6, the display panel DP may include the base layer BS, a circuit element layer DP-CL, a display element layer DP-OLED, and an encapsulation layer TFE.

The base layer BS may include a synthetic resin film. The base layer BS may include a glass substrate, a metal substrate, or an organic/inorganic composite substrate. As an example, the base layer BS may be a silicon substrate containing silicon. The base layer BS may be a silicon wafer.

At least one inorganic layer may be located on an upper surface of the base layer BS. A buffer layer BFL may increase a coupling force between the base layer BS and a semiconductor pattern. The buffer layer BFL may include a silicon oxide layer and a silicon nitride layer, and the silicon oxide layer and the silicon nitride layer may be alternately stacked with each other.

The display panel DP may include a plurality of insulating layers, a semiconductor pattern, a conductive pattern, and a signal line. An insulating layer, a semiconductor layer, and a conductive layer may be formed by coating and deposition processes. Then, the insulating layer, the semiconductor layer, and the conductive layer may be selectively patterned by a photolithography process and an etching process. The semiconductor pattern, the conductive pattern, and the signal line, which are included in the circuit element layer DP-CL and the display element layer DP-OLED, may be formed by the above-mentioned method.

The semiconductor pattern may be located on the buffer layer BFL. The semiconductor pattern may include polysilicon, however, it should not be limited thereto or thereby. According to some embodiments, the semiconductor pattern may include amorphous silicon or metal oxide. The semiconductor pattern may be arranged with a specific rule over a plurality of light emitting areas. The semiconductor pattern may have different electrical properties depending on whether it is doped or not or whether it is doped with an N-type dopant or a P-type dopant. The semiconductor pattern may include a first region having a relatively high conductivity and a second region having a relatively low conductivity. The first region may be doped with the N-type dopant or the P-type dopant. A P-type transistor may include the first region doped with the P-type dopant.

The first region may have a conductivity greater than that of the second region and may substantially serve as an electrode or signal line. The second region may substantially correspond to an active (or a channel) of a transistor. In other words, a portion of the semiconductor pattern may be the active of the transistor, another portion of the semiconductor pattern may be a source or a drain of the transistor, and the other portion of the semiconductor pattern may be a conductive area.

As shown in FIG. 6, a source S1, an active A1, and a drain D1 of a transistor T1 may be formed from the semiconductor pattern. FIG. 6 shows a portion of a signal transmission line SCL formed from the semiconductor pattern. According to some embodiments, the signal transmission line SCL may be connected to the drain D1 of the transistor T1 when viewed in the plane (or in a plan view, or when viewed from the third direction DR3).

First, second, third, fourth insulating layers 10, 20, 30, 40 and first and second auxiliary insulating layers 50 and 60 may be located on the buffer layer BFL. Each of the first insulating layer 10 to the second auxiliary insulating layer 60 may be an inorganic layer or an organic layer. A gate G1 may be located on the first insulating layer 10. An upper electrode UE may be located on the second insulating layer 20. A first connection electrode CNE1 may be located on the third insulating layer 30. The first connection electrode CNE1 may be connected to the signal transmission line SCL via a contact hole CNT-1 defined through the first, second, and third insulating layers 10, 20, and 30. The fourth insulating layer 40 and the first auxiliary insulating layer 50 may be located on the third insulating layer 30. According to some embodiments, each of the fourth insulating layer 40 and the first auxiliary insulating layer 50 may be an organic layer. The first auxiliary insulating layer 50 and the second auxiliary insulating layer 60 will be described in detail later with reference to FIG. 7.

A second connection electrode CNE2 may be located on the first auxiliary insulating layer 50. The second connection electrode CNE2 may be connected to the first connection electrode CNE1 via a contact hole CNT-2 defined through the fourth insulating layer 40 and the first auxiliary insulating layer 50.

The display element layer DP-OLED may be located on the circuit element layer DP-CL. According to some embodiments, the display element layer DP-OLED may include a light emitting element OLED, a pixel definition layer PDL, and a capping layer CPL.

The light emitting element OLED may be located on the second auxiliary insulating layer 60. According to some embodiments, the light emitting element OLED may include the first electrode AE and a second electrode CE. The light emitting element OLED may further include an intermediate layer ML located between the first electrode AE and the second electrode CE. The intermediate layer ML may include a hole control layer HCL, the light emitting layer EML, and an electron control layer ECL. A portion of the intermediate layer ML may overlap a pixel opening OP-P when viewed in the plane (or in a plan view, or when viewed from the third direction DR3). The intermediate layer ML may include a first contact portion TP1 (refer to FIG. 7) located on a first auxiliary electrode SD1 (refer to FIG. 7). The first contact portion TP1 (refer to FIG. 7) will be described in detail later.

The first electrode AE may be located on the second auxiliary insulating layer 60. The first electrode AE may be connected to the second connection electrode CNE2 via a contact hole CNT-3 defined through the second auxiliary insulating layer 60. The pixel definition layer PDL may be located on the second auxiliary insulating layer 60. The pixel opening OP-P may be defined through the pixel definition layer PDL. At least a portion of the first electrode AE may be exposed through the pixel opening OP-P. At least the portion of the first electrode AE may be located in the pixel opening OP-P.

The pixel definition layer PDL may have a light absorbing material. The pixel definition layer PDL may include a black coloring agent. The black coloring agent may include a black dye or a black pigment. The black coloring agent may include a metal material, such as carbon black, chromium, or an oxide thereof.

The hole control layer HCL may be located on the first electrode AE. The hole control layer HCL may be commonly arranged in the third pixel area PXA-G and the non-light-emitting area NPXA. The hole control layer HCL may include a hole transport layer and may further include a hole injection layer.

The light emitting layer EML may be located between the first electrode AE and the second electrode CE. The light emitting layer EML may be located on the hole control layer HCL. The light emitting layer EML may be commonly arranged in the third pixel area PXA-G and the non-light-emitting area NPXA.

The electron control layer ECL may be located on the light emitting layer EML. The electron control layer ECL may include an electron transport layer and may further include an electron injection layer.

The second electrode CE may be located above the first electrode AE. The second electrode CE may be located on the electron control layer ECL. The electron control layer ECL and the second electrode CE may be commonly arranged in the third pixel area PXA-G and the non-light-emitting area NPXA. The second electrode CE may be electrically connected to the first auxiliary electrode SD1 (refer to FIG. 7). The second electrode CE may include a second contact portion TP2 (refer to FIG. 7) that is directly in contact with the first auxiliary electrode SD1 (refer to FIG. 7). The second contact portion TP2 (refer to FIG. 7) will be described in detail later.

The capping layer CPL may be located on the second electrode CE. The capping layer CPL may be commonly located in the third pixel area PXA-G and the non-light-emitting area NPXA.

According to some embodiments, the capping layer CPL may include an inorganic material. The capping layer CPL may be formed through a sputtering deposition process.

The capping layer CPL may cover the second electrode CE and thus may protect the second electrode CE and the light emitting layer EML from external moisture and contaminants. In addition, a light totally reflected at an interface between the second electrode CE and the capping layer CPL may be reduced by adjusting a refractive index and a thickness of the capping layer CPL.

The encapsulation layer TFE may be located on the display element layer DP-OLED. The encapsulation layer TFE may encapsulate the display element layer DP-OLED. The encapsulation layer TFE may include a single layer or a plurality of layers stacked on each other. The encapsulation layer TFE may include at least one organic layer.

According to some embodiments, the encapsulation layer TFE may include a first inorganic layer IOL1, an organic layer OL, and a second inorganic layer IOL2. The first inorganic layer IOL1 may be located on the capping layer CPL. The organic layer OL may be located on the first inorganic layer IOL1. The second inorganic layer IOL2 may be located on the organic layer OL and may cover the organic layer OL.

The first inorganic layer IOL1 and the second inorganic layer IOL2 may protect the display element layer DP-OLED from moisture and oxygen, and the organic layer OL may protect the display element layer DP-OLED from a foreign substance such as dust particles.

FIGS. 7 and 8 are cross-sectional views of the display devices taken along a line II-II′ of FIG. 5 according to some embodiments of the present disclosure. FIG. 7 shows the display device in which the first opening area OA1 is formed, and FIG. 8 shows the display device in which the second opening area OA2 is formed. Descriptions of the components described with reference to FIG. 6 will be omitted in order to avoid redundancy.

Referring to FIG. 7, the circuit element layer DP-CL (refer to FIG. 6) may include the first auxiliary insulating layer 50, the second auxiliary insulating layer 60, the first auxiliary electrode SD1, and a second auxiliary electrode SD2. The first auxiliary electrode SD1 may be located on the fourth insulating layer 40. The first auxiliary electrode SD1 may be located directly on the fourth insulating layer 40. The first auxiliary electrode SD1 may be a conductor. The first auxiliary electrode SD1 may include the same material as the first connection electrode CNE1 (refer to FIG. 6). The first auxiliary electrode SD1 may include an upper surface U-SD1 substantially parallel to the first direction DR1. The first contact portion TP1 and the second contact portion TP2 may be located on the upper surface U-SD1 of the first auxiliary electrode SD1. The first contact portion TP1 and the second contact portion TP2 may be located directly on the upper surface U-SD1 of the first auxiliary electrode SD1. When the second contact portion TP2 is located directly on the upper surface U-SD1 of the first auxiliary electrode SD1, the second electrode CE may be electrically connected to the first auxiliary electrode SD1. When the second contact portion TP2 of the second electrode CE is located directly on the first auxiliary electrode SD1, electrons moving through the second electrode CE move via the first auxiliary electrode SD1. Accordingly, a cross-sectional area of a path through which the electrons move may increase, and thus, a resistance may be reduced.

The first auxiliary insulating layer 50 may be located on the first auxiliary electrode SD1. The first auxiliary insulating layer 50 may be located directly on the first auxiliary electrode SD1. The first auxiliary insulating layer 50 may overlap a portion of the first auxiliary electrode SD1 when viewed in the plane (or in a plan view, or when viewed from the third direction DR3). An opening OP may be defined through the first auxiliary insulating layer 50. The opening OP may overlap the first opening area OA1 when viewed in the plane (or in a plan view, or when viewed from the third direction DR3). The opening OP may not overlap the pixel opening OP-P (refer to FIG. 5) when viewed in the plane (or in a plan view, or when viewed from the third direction DR3). The opening OP may have a diameter equal to or greater than about 10 micrometers and equal to or smaller than about 15 micrometers when viewed in the plane. As an example, the diameter of the opening OP may be about 10 micrometers when viewed in the plane (or in a plan view, or when viewed from the third direction DR3). The opening OP may be used as a space where the second electrode CE is electrically connected to the first auxiliary electrode SD1. At least a portion of the first auxiliary electrode SD1 may be located in the opening OP. At least the portion of the first auxiliary electrode SD1 may be exposed through the opening OP.

The second auxiliary electrode SD2 may include a second-first portion SD2-1 located on the first auxiliary electrode SD1 and a second-second portion SD2-2 spaced apart from the upper surface U-SD1 of the first auxiliary electrode SD1. The second auxiliary electrode SD2 may further include a second-third portion SD2-3 spaced apart from the upper surface U-SD1 of the first auxiliary electrode SD1. The second-second portion SD2-2 may extend and protrude from one side of the second-first portion SD2-1. The second-third portion SD2-3 may extend and protrude from the other side of the second-first portion SD2-1. At least a portion of the second auxiliary electrode SD2 may be located in the opening OP. The second auxiliary electrode SD2 may include the same material as the second connection electrode CNE2 (refer to FIG. 6). A size of the second auxiliary electrode SD2 may be smaller than a size of the first auxiliary electrode SD1 when viewed in the plane (or in a plan view, or when viewed from the third direction DR3).

The second-first portion SD2-1 may be located directly on the first auxiliary electrode SD1. The second-first portion SD2-1 may electrically connect the first auxiliary electrode SD1 and the second auxiliary electrode SD2.

The second-second portion SD2-2 may include a first surface SDS1 that forms a first angle AG1 with the upper surface U-SD1 of the first auxiliary electrode SD1. The first angle AG1 may be an acute angle. In a case where the first angle AG1 is an obtuse angle rather than the acute angle, a difficulty of the manufacturing process of the display device may increase. The second-second portion SD2-2 may be located in the opening OP. A portion of the second-second portion SD2-2 may be exposed through the opening OP. The second contact portion TP2 may be located between the first contact portion TP1 and the first surface SDS1. The second contact portion TP2 may overlap the second-second portion SD2-2 when viewed in the plane (or in a plan view, or when viewed from the third direction DR3). The first contact portion TP1 may not overlap the second-second portion SD2-2 when viewed in the plane (or in a plan view, or when viewed from the third direction DR3).

The second auxiliary insulating layer 60 may be located on the first auxiliary insulating layer 50. The second auxiliary insulating layer 60 may be located directly on the first auxiliary insulating layer 50. The second auxiliary insulating layer 60 may overlap the opening OP when viewed in the plane (or in a plan view, or when viewed from the third direction DR3). The opening OP may penetrate the second auxiliary insulating layer 60 and the pixel definition layer PDL. The opening OP may be a space where a portion of each of the intermediate layer ML and the second electrode CE is located directly on the first auxiliary electrode SD1. A portion of the second auxiliary insulating layer 60 may be located on the second auxiliary electrode SD2. The second auxiliary insulating layer 60 may not overlap each of the first contact portion TP1 and the second contact portion TP2 when viewed in the plane (or in a plan view, or when viewed from the third direction DR3).

Referring to FIG. 8, the second opening area OA2 may overlap a second auxiliary electrode SD2 when viewed in the plane (or in a plan view, or when viewed from the third direction DR3). When compared with the first opening area OA1 shown in FIG. 7, an opening OP may overlap an entire portion of the second auxiliary electrode SD2 instead of overlapping only a portion of the second auxiliary electrode SD2 in the second opening area OA2 shown in FIG. 8.

The second auxiliary electrode SD2 may include the second-first portion SD2-1 located on the first auxiliary electrode SD1 and the second-second portion SD2-2 spaced apart from the upper surface U-SD1 of the first auxiliary electrode SD1. The second auxiliary electrode SD2 may further include a second-third portion SD2-3. A portion of the second-third portion SD2-3 may be exposed through the opening OP. The second-third portion SD2-3 may include a second surface SDS2 that forms a second angle AG2 with an upper surface U-SD1 of a first auxiliary electrode SD1. The second angle AG2 may be an acute angle. A first angle AG1 may be substantially the same as the second angle AG2. In a case where the second angle AG2 is an obtuse angle rather than the acute angle, a difficulty of the manufacturing process of the display device may increase. The second surface SDS2 may be exposed through the opening OP. A second contact portion TP2 may be located between a first contact portion TP1 and the second surface SDS2.

The second opening area OA2 may be wider than the first opening area OA1 (refer to FIG. 7) when viewed in the plane (or in a plan view, or when viewed from the third direction DR3). Because the second-third portion SD2-3 is exposed through the opening OP of the second opening area OA2, the second contact portion TP2 may be further located between the first contact portion TP1 and the second surface SDS2 in addition to between a second-first portion SD2-1 and the first contact portion TP1. When the second contact portion TP2 is further located between the first contact portion TP1 and the second surface SDS2, an area where the second contact portion TP2 is in contact with the first auxiliary electrode SD1 may increase, and thus, an electrical resistance of the second electrode CE may be further reduced.

Hereinafter, a method of manufacturing the display device will be described. Details of the components described with reference to FIGS. 1 to 8 will be omitted.

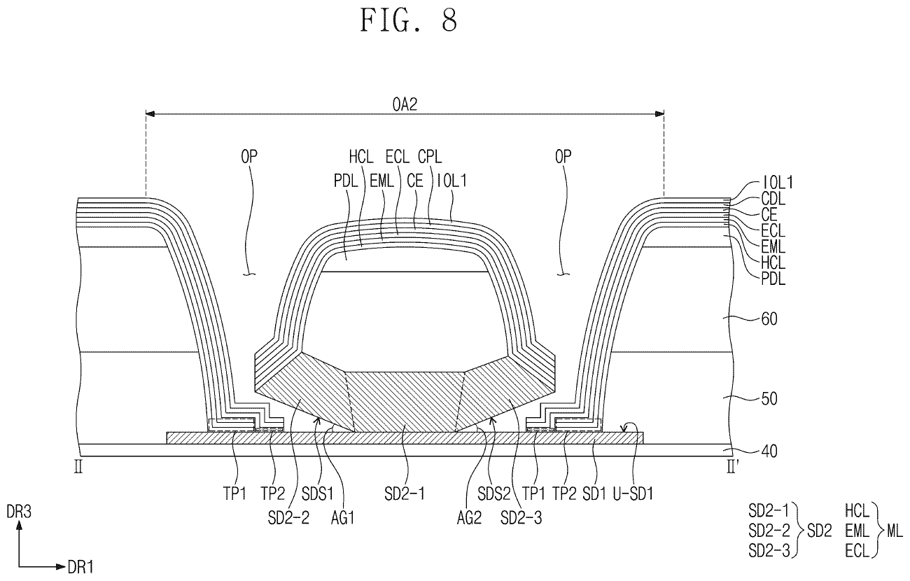

FIG. 9 is a flowchart of the manufacturing method of the display device according to some embodiments of the present disclosure. Although various operations are illustrated in FIG. 9, embodiments according to the present disclosure may include additional operations or fewer operations, or the order of operations may vary, unless otherwise explicitly stated or implied, without departing from the spirit and scope of embodiments according to the present disclosure

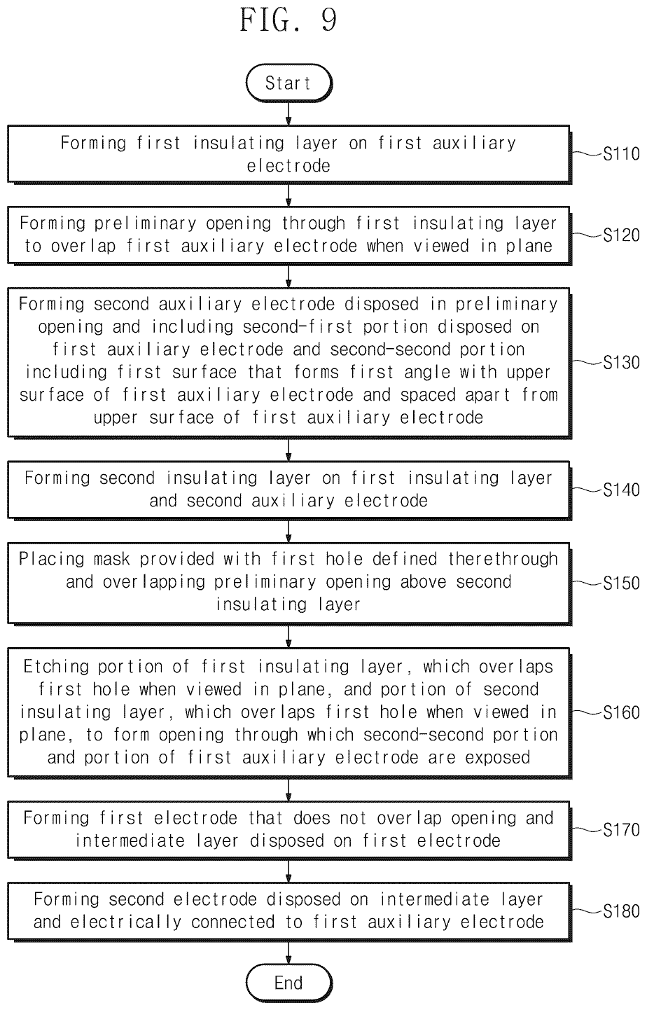

FIGS. 10 to 17 are cross-sectional views of processes of the manufacturing method of the display device according to some embodiments of the present disclosure.

Referring to FIG. 9, the manufacturing method of the display device may include forming the first auxiliary insulating layer on the first auxiliary electrode (S110), forming a preliminary opening through the first auxiliary insulating layer to overlap the first auxiliary electrode when viewed in the plane (or in a plan view, or when viewed from the third direction DR3) (S120), forming the second auxiliary electrode located in the preliminary opening and including the second-first portion located on the first auxiliary electrode and the second-second portion including the first surface that forms the first angle with the upper surface of the first auxiliary electrode and spaced apart from the upper surface of the first auxiliary electrode (S130), forming the second auxiliary insulating layer on the first auxiliary insulating layer and the second auxiliary electrode (S140), placing a mask provided with a first hole defined therethrough and overlapping the preliminary opening above the second auxiliary insulating layer (S150), etching a portion of the first auxiliary insulating layer, which overlaps the first hole when viewed in the plane (or in a plan view, or when viewed from the third direction DR3), and a portion of the second auxiliary insulating layer, which overlaps the first hole when viewed in the plane (or in a plan view, or when viewed from the third direction DR3), to form the opening through which the second-second portion and the portion of the first auxiliary electrode are exposed (S160), forming the first electrode, which does not overlap the opening, and the intermediate layer located on the first electrode (S170), and forming the second electrode located on the intermediate layer and electrically connected to the first auxiliary electrode (S180).

Referring to FIGS. 9 and 10, the manufacturing method of the display device may include the forming of the first auxiliary insulating layer 50 on the first auxiliary electrode SD1 (S110). The first auxiliary electrode SD1 may be formed on the fourth insulating layer 40, and, according to some embodiments, the third insulating layer 30 (refer to FIG. 6), the second insulating layer 20 (refer to FIG. 6), the first insulating layer 10 (refer to FIG. 6), the buffer layer BFL (refer to FIGS. 6), and the base layer BS (refer to FIG. 6) may be sequentially located on a lower surface of the fourth insulating layer 40 (refer to FIG. 6) along a direction opposite to the third direction DR3. The first auxiliary insulating layer 50 may be formed to cover the upper surface and a side surface of the first auxiliary electrode SD1.

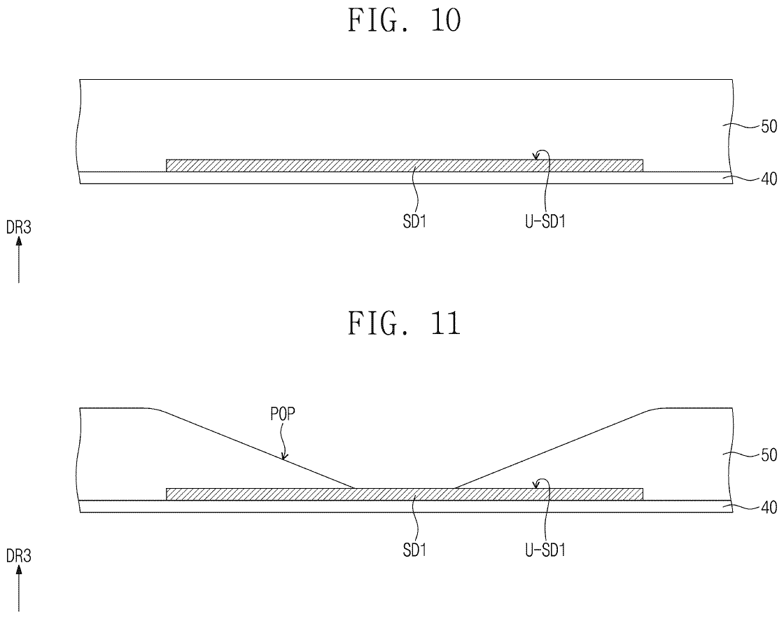

Referring to FIGS. 9 and 11, the manufacturing method of the display device may include the forming of the preliminary opening POP through the first auxiliary insulating layer 50 to overlap the first auxiliary electrode SD1 when viewed in the plane (or in a plan view, or when viewed from the third direction DR3) (S120). The preliminary opening POP may be formed by etching a portion of the first auxiliary insulating layer 50. The preliminary opening POP may be formed by dry etching the portion of the first auxiliary insulating layer 50. The preliminary opening POP may completely penetrate the first auxiliary insulating layer 50. The portion of the first auxiliary electrode SD1 may be exposed through the preliminary opening POP.

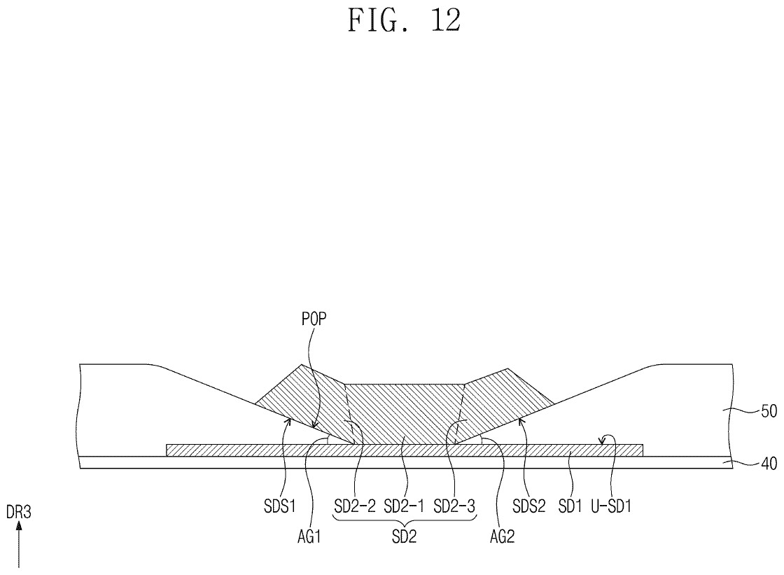

Referring to FIGS. 9 and 12, the manufacturing method of the display device may include the forming of the second auxiliary electrode SD2 located in the preliminary opening POP and including the second-first portion SD2-1 located on the first auxiliary electrode SD1 and the second-second portion SD2-2 including the first surface SDS1 that forms the first angle AG1 with the upper surface U-SD1 of the first auxiliary electrode SD1 and spaced apart from the upper surface U-SD1 of the first auxiliary electrode SD1 (S130). The first angle AG1 may be an acute angle. In a case where the first angle AG1 is an obtuse angle, the difficulty of the manufacturing process of the display device may increase. The forming of the second auxiliary electrode SD2 (S130) may include forming the second-third portion including the second surface SDS2 that forms the second angle AG2 with the upper surface U-SD1 of the first auxiliary electrode SD1 and spaced apart from the upper surface U-SD1 of the first auxiliary electrode SD1. The second angle AG2 may be an acute angle. In a case where the second angle AG2 is an obtuse angle, the difficulty of the manufacturing process of the display device may increase. The first angle AG1 may be substantially the same as the second angle AG2. The second-second portion SD2-2 and the second-third portion SD2-3 may be located directly on the first auxiliary insulating layer 50. The second-first portion SD2-1 may be located directly on the first auxiliary electrode SD1. The second-first portion SD2-1 may be located directly on the portion of the first auxiliary electrode SD1 exposed through the preliminary opening POP.

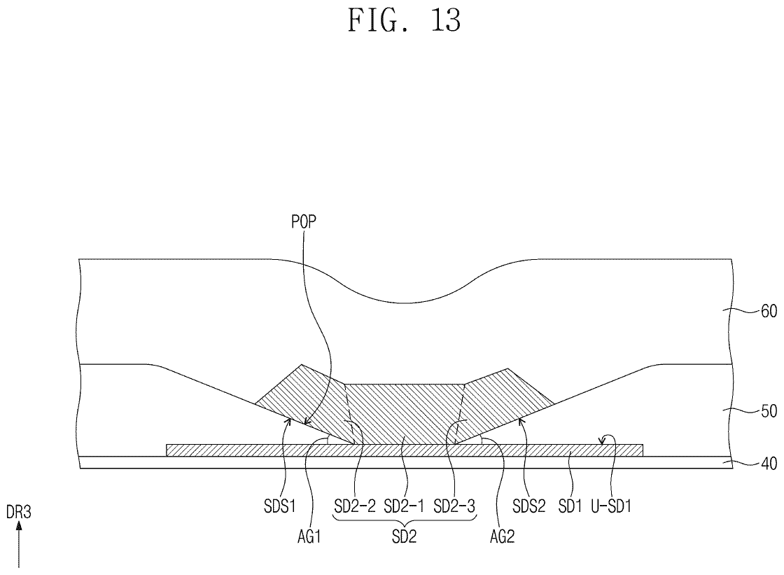

Referring to FIGS. 9 and 13, the manufacturing method of the display device may include the forming of the second auxiliary insulating layer 60 on the first auxiliary insulating layer 50 and the second auxiliary electrode SD2 (S140). The second auxiliary insulating layer 60 may be located directly on the first auxiliary insulating layer 50 and the second auxiliary electrode SD2. The second auxiliary insulating layer 60 may cover the first auxiliary insulating layer 50 and the second auxiliary electrode SD2. A portion of the second auxiliary insulating layer 60 may be concaved in an area where the second auxiliary insulating layer 60 overlaps the second-first portion SD2-1 when viewed in the plane (or in a plan view, or when viewed from the third direction DR3).

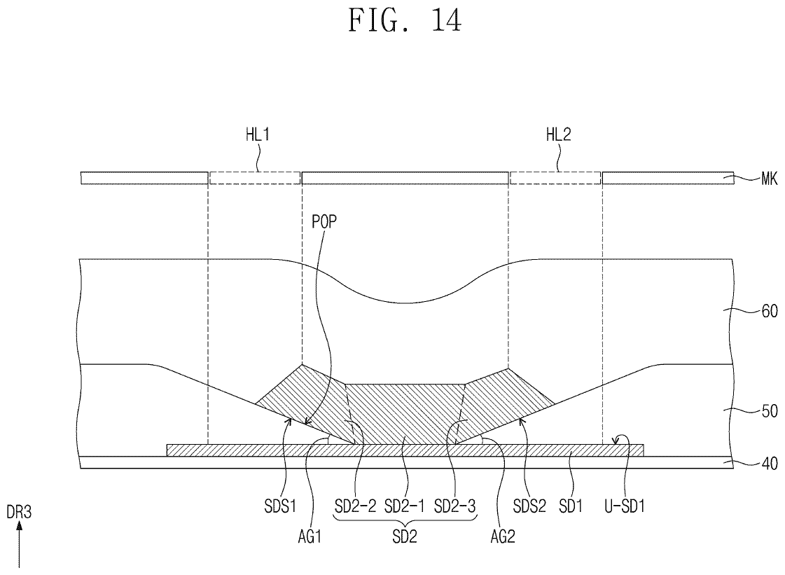

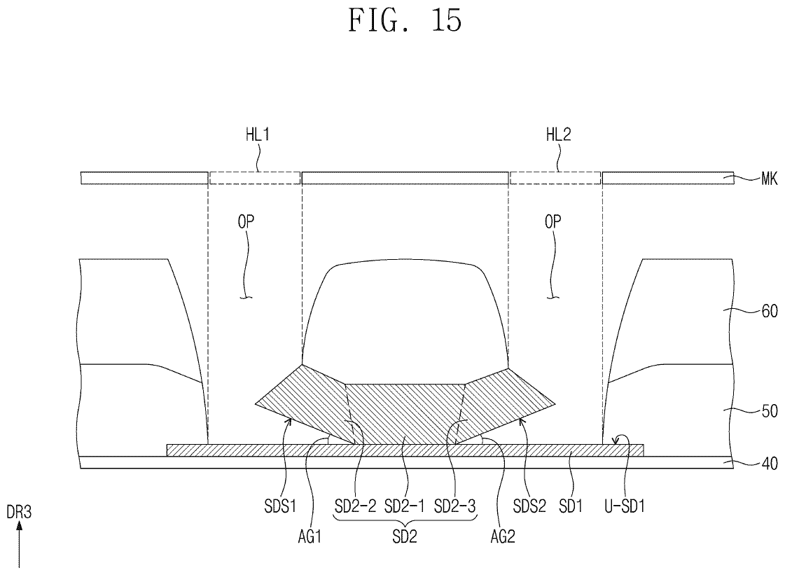

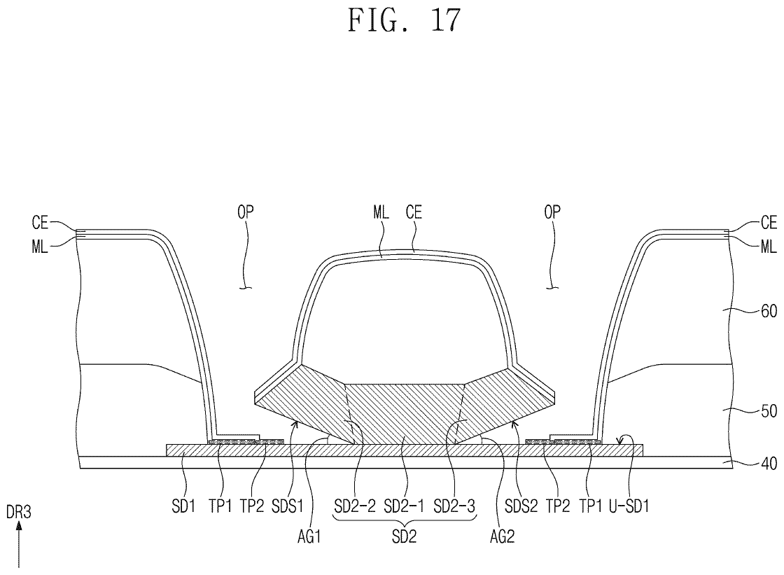

Referring to FIGS. 9, 14, and 15, the manufacturing method of the display device may include the placing of the mask MK provided with the first hole HL1 defined therethrough and overlapping the preliminary opening POP above the second auxiliary insulating layer 60 (S150) and the etching of the portion of the first auxiliary insulating layer 50, which overlaps the first hole HL1 when viewed in the plane (or in a plan view, or when viewed from the third direction DR3), and the portion of the second auxiliary insulating layer 60 which overlaps the first hole HL1 when viewed in the plane (or in a plan view, or when viewed from the third direction DR3), to form the opening OP through which the second-second portion SD2-2 and the portion of the first auxiliary electrode SD1 are exposed (S160). The mask MK may be located spaced apart from the second auxiliary insulating layer 60 in the third direction DR3. The first hole HL1 may not overlap the second-first portion SD2-1 when viewed in the plane (or in a plan view, or when viewed from the third direction DR3), and thus, the second auxiliary insulating layer 60 located on the second-first portion SD2-1 may not be etched. When the first hole HL1 does not overlap the second-first portion SD2-1 when viewed in the plane (or in a plan view, or when viewed from the third direction DR3), the etched portion of the second auxiliary insulating layer 60 may be reduced, and an efficiency of the etching process may be improved. The mask MK may further include a second hole HL2 defined therethrough and overlapping the preliminary opening POP when viewed in the plane (or in a plan view, or when viewed from the third direction DR3). Different from the structures shown in FIGS. 14 and 15, the second hole HL2 may not be defined through the mask MK, and the first hole HL1 may overlap the second-first portion SD2-1, at least a portion of the first auxiliary insulating layer 50, and the second-third portion SD2-3 when viewed in the plane. When the first hole HL1 overlaps the second-first portion SD2-1, the at least the portion of the first auxiliary insulating layer 50, and the second-third portion SD2-3 when viewed in the plane (or in a plan view, or when viewed from the third direction DR3), a size of the opening OP may increase in the plane (or in a plan view, or when viewed from the third direction DR3), a contact area where the second electrode CE (refer to FIG. 17) is in contact with the first auxiliary electrode SD1 may increase, and thus, an electrical resistance may be effectively reduced compared with the structure in which the second surface SDS2 (refer to FIG. 8) is not exposed and the portion of the second electrode CE is not located between the upper surface U-SD1 and the second surface SDS2 (refer to FIG. 8) as shown in FIG. 7. The portion of the first auxiliary insulating layer 50, which overlaps the first hole HL1 when viewed in the plane (or in a plan view, or when viewed from the third direction DR3), and the portion of the second auxiliary insulating layer 60, which overlaps the first hole HL1 when viewed in the plane (or in a plan view, or when viewed from the third direction DR3), may be etched by a dry etch.

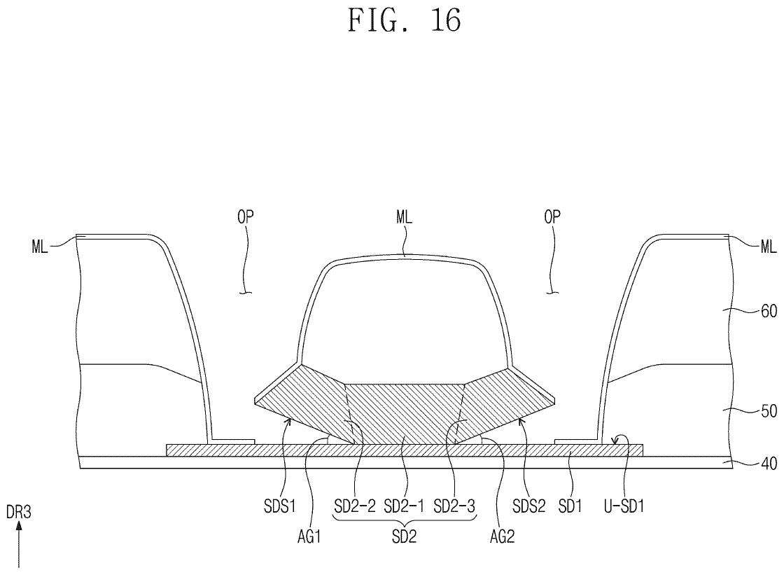

Referring to FIGS. 9 and 16, the manufacturing method of the display device may include the forming of the first electrode AE (refer to FIG. 6), which does not overlap the opening OP, and the intermediate layer ML located on the first electrode AE (refer to FIG. 6) (S170). The first electrode AE may be located on the second auxiliary insulating layer 60. The forming of the intermediate layer ML (S170) may include spraying a material for the intermediate layer ML to the direction opposite to the third direction DR3. As an example, the material for the intermediate layer ML may include an organic electroluminescent material. A portion of the intermediate layer ML located directly on the first auxiliary electrode SD1 may not overlap the second-second portion SD2-2 when viewed in the plane (or in a plan view, or when viewed from the third direction DR3). The intermediate layer ML may be located on the second auxiliary insulating layer 60, the second-second portion SD2-2, the second-third portion SD2-3, and the first auxiliary electrode SD1. Different from the structure shown in FIG. 16, the second auxiliary insulating layer 60 may not be located on the second auxiliary electrode SD2, and in this case, the intermediate layer ML may be located directly on the second auxiliary electrode SD2.

Referring to FIGS. 9 and 17, the manufacturing method of the display device may include the forming of the second electrode CE located on the intermediate layer ML and electrically connected to the first auxiliary electrode SD1 (S180). The forming of the second electrode CE (S180) may include spraying a material for the second electrode CE to a direction inclined with respect to the third direction DR3 to form the second contact portion TP2 located directly on the first auxiliary electrode SD1. The material for the second electrode CE may include indium tin oxide (ITO), indium zinc oxide (IZO), zinc oxide (ZnO), indium tin zinc oxide (ITZO), Ag, Mg, Cu, Al, Pt, Pd, Au, Ni, Nd, Ir, Cr, Li, Ca, LiF/Ca, LiF/Al, Mo, Ti, Yb, a compound thereof, e.g., AgYb or AgMg and MgAg compounds depending on content, etc., or a mixture thereof, e.g., a mixture Ag and Mg. Because the first surface SDS1 is spaced apart from the upper surface U-SD1 of the first auxiliary electrode SD1 while forming the first angle AG1 with the upper surface U-SD1 of the first auxiliary electrode SD1, the material for the second electrode CE may be sprayed to the direction forming an angle (e.g., a set or predetermined angle) with the direction opposite to the third direction DR3, and the second contact portion TP2 may be located directly on the first auxiliary electrode SD1. The angle at which the material for the second electrode CE is sprayed and the angle at which the material for the intermediate layer ML is sprayed may form an angle (e.g., a set or predetermined angle), and the portion of the second electrode CE may be located directly on the first auxiliary electrode SD1. The manufacturing method of the display device is advantageous in improving the integration of the display device because the size of the opening is relatively small compared with a conventional manufacturing method allowing a portion of a second electrode to be in contact with an auxiliary electrode by providing an intermediate layer as a common layer and forming an opening through the intermediate layer using a laser drill. The second electrode CE may include the second contact portion TP2 located directly on the first auxiliary electrode SD1. The second electrode CE may be electrically connected to the first auxiliary electrode SD1 via the second contact portion TP2. The second auxiliary electrode SD2 may be located directly on the first auxiliary electrode SD1 and may be electrically connected to the first auxiliary electrode SD1. The second electrode CE may be electrically connected to the first auxiliary electrode SD1 and the second auxiliary electrode SD2 via the second contact portion TP2. Thus, the cross-sectional area of the path through which the electrons move may increase, and thus, the electrical resistance may be reduced.

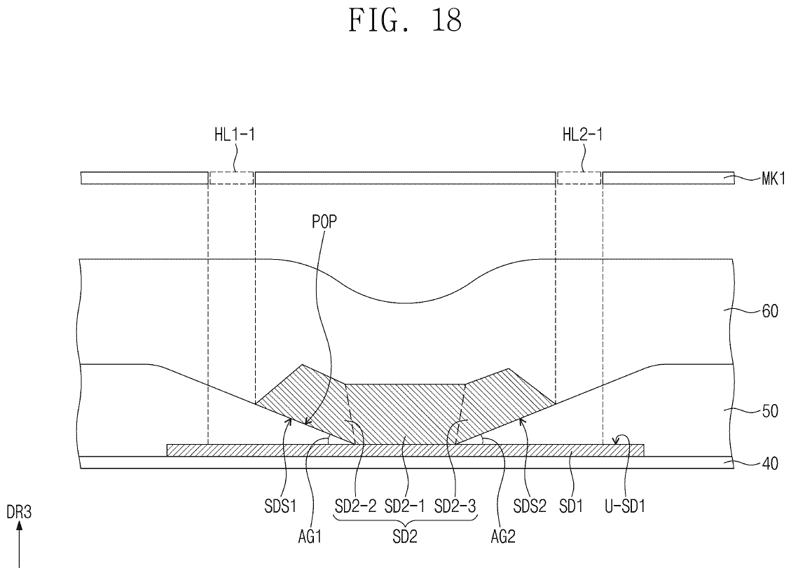

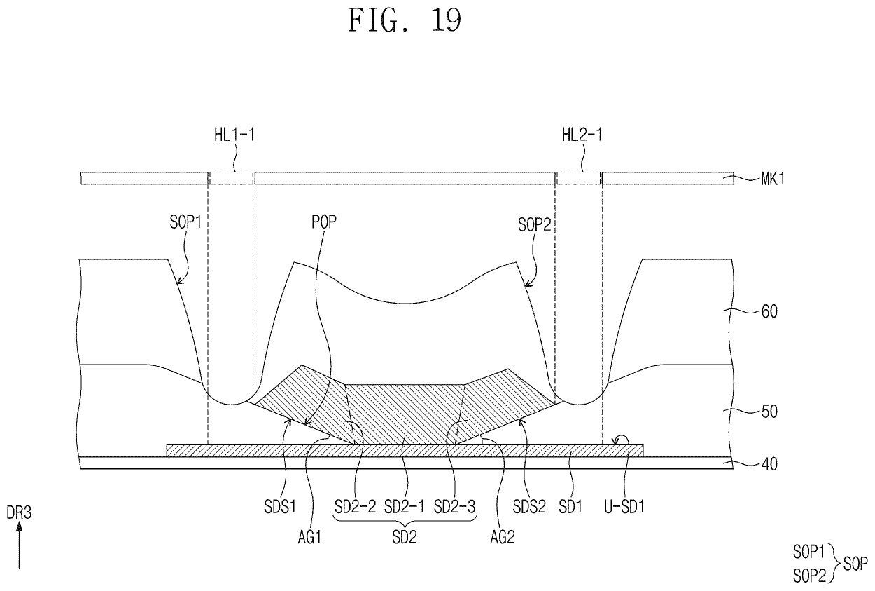

Referring to FIGS. 18 and 19, the manufacturing method of the display device may further include etching a portion of the first auxiliary insulating layer 50 which overlap the first auxiliary electrode SD1 when viewed in the plane (or in a plan view, or when viewed from the third direction DR3) and do not overlap the second auxiliary electrode SD2 when viewed in the plane (or in a plan view, or when viewed from the third direction DR3), and a portion of the second auxiliary insulating layer 60 to form a sub-opening SOP before the forming of the opening. A first mask MK1 through which a first-first hole HL1-1 and a first-second hole HL1-2 are formed may be located above the second auxiliary insulating layer 60 to form the sub-opening SOP. Each of the first-first hole HL1-1 and the first-second hole HL1-2 may not overlap the second auxiliary electrode SD2 when viewed in the plane (or in a plan view, or when viewed from the third direction DR3). The etching process to form the sub-opening SOP may be a dry etching process. The sub-opening SOP may include a first sub-opening SOP1 and a second sub-opening SOP2. The second-first portion SD2-1 may not be exposed through the first sub-opening SOP1. The second-third portion SD2-3 may not be exposed through the second sub-opening SOP2. A depth of the opening OP (refer to FIG. 16) may be greater than a depth of the sub-opening SOP. The sub-opening SOP may not completely penetrate the first auxiliary insulating layer 50. The sub-opening SOP may be formed to lower a difficulty of the process of forming the opening OP (refer to FIG. 16). In the case where the sub-opening SOP is formed before the opening OP (refer to FIG. 16) is formed, the time and energy required to form the opening OP (refer to FIG. 16) may be reduced, and the portion of the first auxiliary insulating layer 50 formed between the second-first portion SD2-1 and the first auxiliary electrode SD1 and the portion of the first auxiliary insulating layer 50 formed between the second-third portion SD2-3 and the first auxiliary electrode SD1 may be effectively etched. When the portion of the first auxiliary insulating layer 50 formed between the second-first portion SD2-1 and the first auxiliary electrode SD1 and the portion of the first auxiliary insulating layer 50 formed between the second-third portion SD2-3 and the first auxiliary electrode SD1 are effectively etched, the space in which the portion of the second electrode CE (refer to FIG. 17) is located directly on the first auxiliary electrode SD1 may be easily formed.

Although aspects of some embodiments of the present disclosure have been described, it is understood that embodiments according to the present disclosure are not limited to these embodiments but various changes and modifications can be made by one ordinary skilled in the art within the spirit and scope of the present disclosure as hereinafter claimed. Therefore, the disclosed subject matter should not be limited to any single embodiment described herein, and the scope of the present inventive concept shall be determined according to the appended claims, and their equivalents.

What is claimed is:

1. A display device comprising:
a first auxiliary insulating layer through which an opening is defined;
a second auxiliary insulating layer on the first auxiliary insulating layer;
a pixel definition layer on the second auxiliary insulating layer and having a pixel opening defined therethrough;
a first auxiliary electrode having at least a portion in the opening;
a second auxiliary electrode having at least a portion in the opening, the second auxiliary electrode comprising a second-first portion on the first auxiliary electrode and a second-second portion comprising a first surface that forms a first angle with an upper surface of the first auxiliary electrode and is spaced apart from the upper surface of the first auxiliary electrode;
a first electrode having a portion in the pixel opening; and
a second electrode on the first electrode and electrically connected to the first auxiliary electrode.

2. The display device of claim 1, wherein the second-second portion is in the opening.

3. The display device of claim 1, wherein a portion of the second auxiliary insulating layer is on the second auxiliary electrode.

4. The display device of claim 1, wherein the first angle is an acute angle.

5. The display device of claim 1, wherein the second-first portion is directly on the first auxiliary electrode.

6. The display device of claim 1, wherein the second auxiliary electrode comprises a second surface forming a second angle with the upper surface of the first auxiliary electrode and further comprises a second-third portion spaced apart from the upper surface of the first auxiliary electrode.

7. The display device of claim 6, wherein the second angle is an acute angle.

8. The display device of claim 1, wherein the pixel opening does not overlap the opening in a plan view.

9. The display device of claim 1, wherein the second auxiliary electrode has an area smaller than an area of the first auxiliary electrode in a plan view.

10. The display device of claim 1, wherein the opening has a diameter equal to or greater than 10 micrometers and equal to or smaller than 15 micrometers in a plan view.

11. The display device of claim 1, further comprising an intermediate layer between the first electrode and the second electrode, wherein a portion of the intermediate layer overlaps the pixel opening in a plan view.

12. The display device of claim 11, wherein the intermediate layer comprises a first contact portion directly on the first auxiliary electrode, the second electrode comprises a second contact portion electrically connected to the first auxiliary electrode, and the second contact portion is between the first contact portion and the first surface and overlaps the second-second portion in the plan view.

13. A display device comprising:
a base layer;
a circuit element layer on the base layer; and
a display element layer on the circuit element layer and comprising a pixel definition layer and a light emitting element, the circuit element layer comprising:
a first auxiliary insulating layer through which an opening is defined;
a second auxiliary insulating layer on the first auxiliary insulating layer;
a first auxiliary electrode having at least a portion in the opening; and
a second auxiliary electrode whose at least a portion is in the opening, the second auxiliary electrode comprising a second-first portion on the first auxiliary electrode and a second-second portion comprising a first surface that forms a first angle with an upper surface of the first auxiliary electrode and spaced apart from the upper surface of the first auxiliary electrode, wherein the pixel definition layer is on the second auxiliary insulating layer and has a pixel opening defined therethrough, the light emitting element comprises:
a first electrode having at least a portion in the pixel opening;
a second electrode on the first electrode and electrically connected to the first auxiliary electrode; and
an intermediate layer between the first electrode and the second electrode, and at least a portion of the intermediate layer is in the pixel opening.

14. The display device of claim 13, wherein the opening does not overlap the pixel opening in a plan view.

15. The display device of claim 13, further comprising an encapsulation layer on the display element layer.

16. A method of manufacturing a display device, comprising:
forming a first auxiliary insulating layer on a first auxiliary electrode;
forming a preliminary opening through the first auxiliary insulating layer to overlap the first auxiliary electrode in a plan view;
forming a second auxiliary electrode in the preliminary opening and comprising a second-first portion on the first auxiliary electrode and a second-second portion comprising a first surface that forms a first angle with an upper surface of the first auxiliary electrode and spaced apart from the upper surface of the first auxiliary electrode;
forming a second auxiliary insulating layer on the first auxiliary insulating layer and the second auxiliary electrode;
placing a mask provided with a first hole defined therethrough and overlapping the preliminary opening above the second auxiliary insulating layer;
etching a portion of the first auxiliary insulating layer, which overlaps the first hole in the plan view, and a portion of the second auxiliary insulating layer, which overlaps the first hole in the plan view, to form an opening through which the second-second portion and the portion of the first auxiliary electrode are exposed;
forming a first electrode that does not overlap the opening and an intermediate layer on the first electrode; and
forming a second electrode on the intermediate layer and electrically connected to the first auxiliary electrode.

17. The method of claim 16, wherein the etching to form the opening is performed by a dry etching process.

18. The method of claim 16, wherein the second auxiliary electrode further comprises a second-third portion comprising a second surface that forms a second angle with the upper surface of the first auxiliary electrode, and the first hole overlaps the second-second portion, at least a portion of the first auxiliary insulating layer, and the second-third portion in the plan view.

19. The method of claim 18, wherein the first hole does not overlap the second-first portion in the plan view.

20. The method of claim 16, further comprising etching a portion of the first auxiliary insulating layer which overlap the first auxiliary electrode in the plan view and do not overlap the second auxiliary electrode in the plan view, and a portion of the second auxiliary insulating layer, to form a sub-opening before the forming of the opening, wherein a depth of the opening is greater than a depth of the sub-opening.
